(19) United States
(12) Patent Application Publication
(10) Pub. No.: US 2022/0384227 A1
(43) Pub. Date: Dec. 1, 2022

(54) SEMICONDUCTOR SUBSTRATE CARRYING CONTAINER WITH INCREASED DIAMETER PURGE PORTS

(71) Applicant: ENTEGRIS, INC., Billerica, MA (US)

(72) Inventor: Matthew A. Fuller, Colorado Springs, CO (US)

(21) Appl. No.: 17/827,243

(22) Filed: May 27, 2022

Related U.S. Application Data
(60) Provisional application No. 63/194,104, filed on May 27, 2021.

(51) Int. Cl. H01L 21/673

(52) U.S. Cl. CPC H01L 21/67393

(57) ABSTRACT

A semiconductor substrate carrying container that includes one or more enlarged purge ports extending through the bottom wall. The purge port(s) permits a purge fluid conditioning element to be inserted into the interior space of the container by installing the purge fluid conditioning element from outside the container through the purge port. The purge port(s) is sized and positioned such that at least a portion of a rear wall of the container is positioned forwardly of a portion of the purge port(s). In addition, a portion of the rear wall is contiguous with a portion of the perimeter of the purge port(s).

### FIELD

This technical disclosure relates to semiconductor substrate carrying containers, for example those used in semiconductor manufacturing.

### BACKGROUND

Substrate carrying containers are used to transport substrates during semiconductor manufacturing. Substrate carrying containers typically include a shell which provides an internal space for holding substrates, and a plate that is used to interface with various conveyors and other devices, for example so that the container can be moved around the processing facility.

### SUMMARY

A semiconductor substrate carrying container is described herein that is provided with one or more purge ports extending through a bottom wall thereof. The purge port(s) is sized to permit a purge fluid conditioning element to be inserted into the interior space of the container by installing the purge fluid conditioning element from outside the container through the purge port. This eliminates the need to install the purge fluid conditioning element from the inside of the container which is required with conventional containers having a conventional sized purge port(s) and which can cause human contamination of the interior environment of the container.

The semiconductor substrate carrying container can be any type of container used to hold and transport semiconductor substrates during semiconductor manufacturing. An example of a semiconductor substrate carrying container includes, but is not limited to, a front opening unified pod (FOUP).

The semiconductor substrates held within the container can be any substrates used in semiconductor manufacturing. Examples of the semiconductor substrates that can be located in the container described herein can include, but are not limited to, wafers and panels (such as flat panels), and combinations thereof.

In an embodiment, the container can include a shell defining an interior space; an opening in the shell, such as but not limited to a front opening, through which semiconductor substrates can be inserted into and removed from the interior space; and a bottom wall with at least one purge port described herein through which a purge fluid conditioning element can be installed into the interior space from outside the container. A plate may be fixed to the bottom wall to interface with various conveyors and other devices so that the container can be moved around a processing facility. The plate may be considered part of the bottom wall of the container or separate from the bottom wall. The plate, if present and considered separate from the bottom wall, may also include an opening that is aligned with the purge port in the bottom wall.

The purge fluid conditioning element can be any type of element that is insertable into the interior space for use in conditioning the environment in the interior space of the container. Examples of purge fluid conditioning elements include, but are not limited to, a diffuser, a getter, a filter, elements that combine one or more of these functions, and others.

In an embodiment, a semiconductor substrate carrying container described herein can include a container shell having an interior space defined by first and second side walls, a top wall, a bottom wall, and a rear wall at a rear of the container shell, where the interior space is sized to be able to receive a plurality of semiconductor substrates therein. A front opening is located at a front of the container shell opposite the rear wall and through which a semiconductor substrate is able to be removed from and inserted into the interior space. In addition, at least one purge port extends through the bottom wall and opens entirely into the interior space. The purge port is sized to allow a purge fluid conditioning element to be installed into the interior space through the purge port from the exterior of the container. Further, in an embodiment, at least a portion of the rear wall may be positioned forwardly of a portion of the purge port.

In another embodiment, a FOUP described herein can include a shell having a front opening and an interior space that is sized to be able to receive a plurality of semiconductor substrates therein. At least one purge port extends through a bottom wall of the shell and opens entirely into the interior space. In addition, at least a portion of a rear wall of the shell is contiguous with a portion of a perimeter of the at least one purge port. As used herein, the word contiguous means that at least a portion of the rear wall and at least a portion of the purge port share a common border, or that at least a portion of the rear wall forms a portion of the perimeter of the opening that defines the at least one purge port.

### DRAWINGS

FIG. 1 is a front perspective view of a semiconductor substrate carrying container having an enlarged purge port.

FIG. 2 is a rear perspective view of the semiconductor substrate carrying container of FIG. 1.

FIG. 3 is a partial top cross-sectional view of the semiconductor substrate carrying container taken along line 3-3 in FIG. 2.

FIG. 4 is a view similar to FIG. 1 showing the beginning of installation of purge fluid conditioning elements into the container.

FIG. 5 depicts an example of purge fluid conditioning elements that have been installed in the semiconductor substrate carrying container from outside the container via the purge ports.

FIG. 6 schematically depicts a top view of the perimeter outline of a base portion of the purge fluid conditioning element.

FIG. 7 depicts an example of a conventional semiconductor substrate carrying container with conventional purge ports.

### DETAILED DESCRIPTION

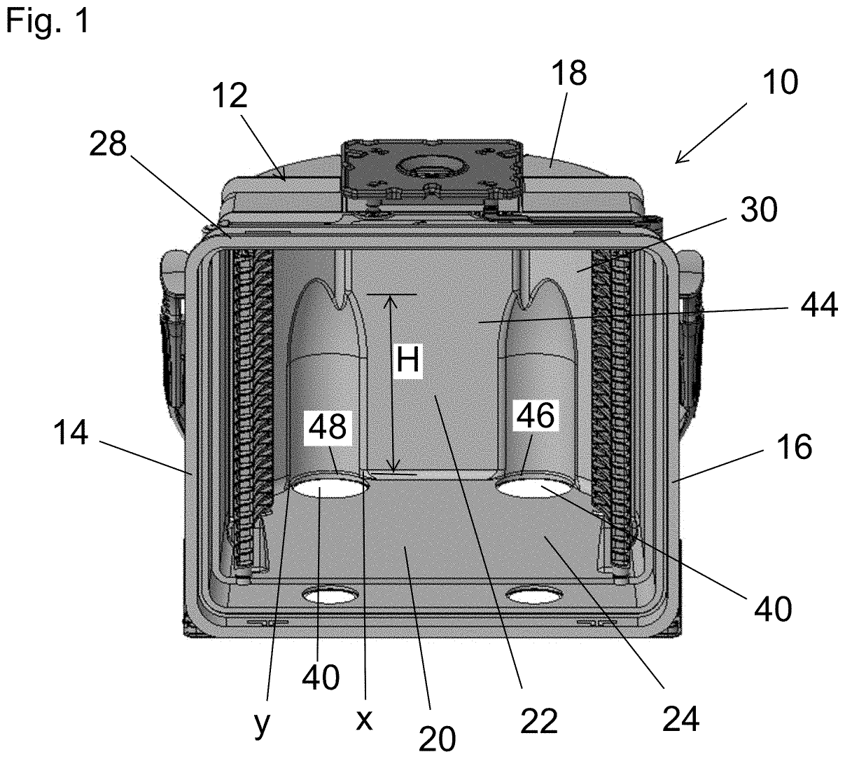

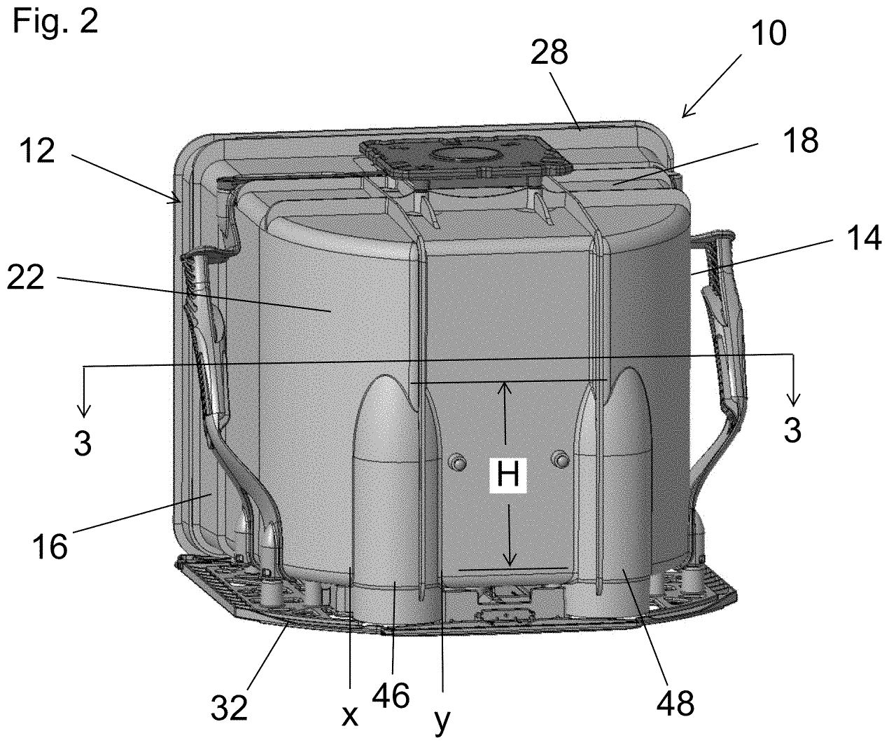

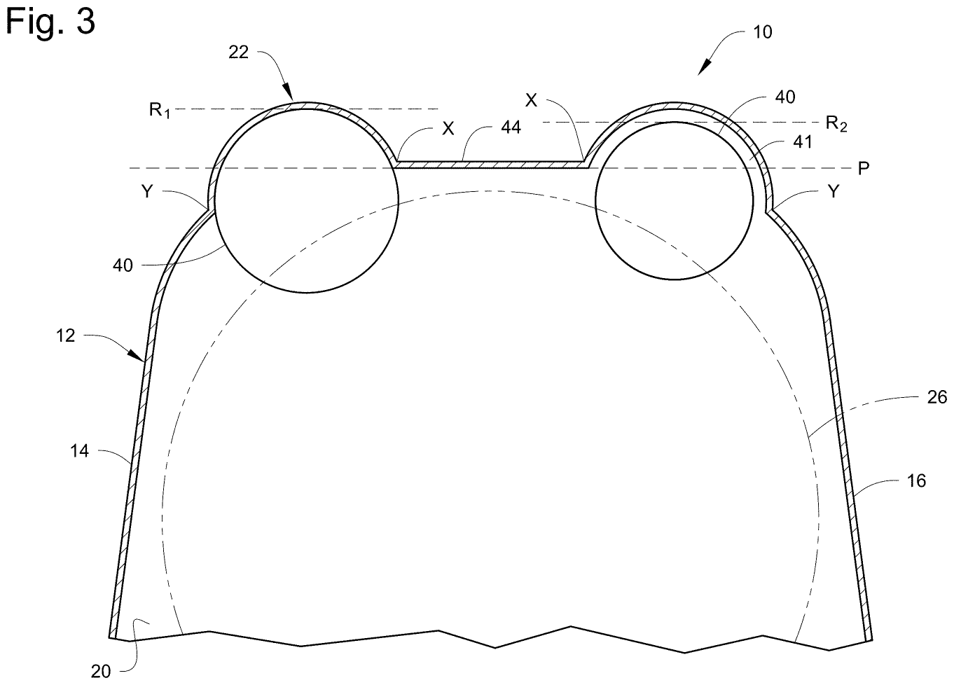

With reference to FIGS. 1-2, an example of a semiconductor substrate carrying container 10 is depicted. In one embodiment, the container 10 may be referred to as a FOUP. The container 10 includes a container shell 12 having a plurality of walls including a first side wall 14, a second side wall 16 opposite the first side wall 14, a top wall 18, a bottom wall 20 (not visible in FIG. 2) opposite the top wall 18, and a rear wall 22. The walls define an interior space 24 (not visible in FIG. 2) that is sized to be able to receive a plurality of semiconductor substrates 26 therein (one semiconductor substrate 26 is shown in dashed lines in FIG. 3) with the substrates 26 in a vertically stacked arrangement where the substrates 26 are vertically spaced from one another and each substrate 26 is oriented horizontally substantially parallel to the top wall 18 and the bottom wall 20. In one embodiment, the container 10 can be configured to receive and hold twenty-four of the substrates 26, although the container 10 can be configured to hold a larger or smaller number of the substrates 26. The substrates 26 can be held in the container 10 in any suitable manner. Techniques for holding substrates in semiconductor substrate carrying containers such as FOUPs is well known in the art.

With continued reference to FIGS. 1 and 2, the container 10 further includes a front 28 having a front opening 30 (visible in FIG. 1) through which each one of the semiconductor substrates 26 is able to be removed from and inserted into the interior space 24. In addition, a machine interface plate 32 (visible in FIG. 2) is secured to the bottom wall 20 of the shell 12. The plate 32 may be considered part of the bottom wall 20 or separate from the bottom wall 20.

The semiconductor substrates 26 can be any substrates used in semiconductor manufacturing. Examples of the semiconductor substrates 26 that can be located in the containers 10 described herein can include, but are not limited to, wafers and panels (such as flat panels), and combinations thereof. FIG. 3 depicts the substrate 26 as being a wafer.

The substrate container 10 can be formed from one or more polymer materials including, but not limited to, injection-moldable polymer materials. The polymer material(s) can include, but are not limited to, one or more polyolefins, one or more polycarbonate, one or more thermoplastic polymers and the like. In an embodiment, some or all of the substrate container 10 can be injection molded. The one or more polymer materials can form a matrix including carbon fill. In an embodiment, the one or more polymer materials can be selected to minimize particle shedding during handling and use of the substrate container 10.

Referring to FIGS. 1 and 3, at least one purge port 40 extends through the bottom wall 20 and opens entirely into the interior space 24. In the illustrated example, the container 10 is depicted as including two of the purge ports 40. However, the container 10 can include a single one of the purge ports 40 or more than two of the purge ports 40. If the plate 32 is present, similar openings are formed in the plate 32 that are aligned with the purge ports 40. The purge ports 40 are depicted as being circular in shape. However, the purge ports 40 can have any shape including, but not limited to, rectangular, square, triangular, and other.

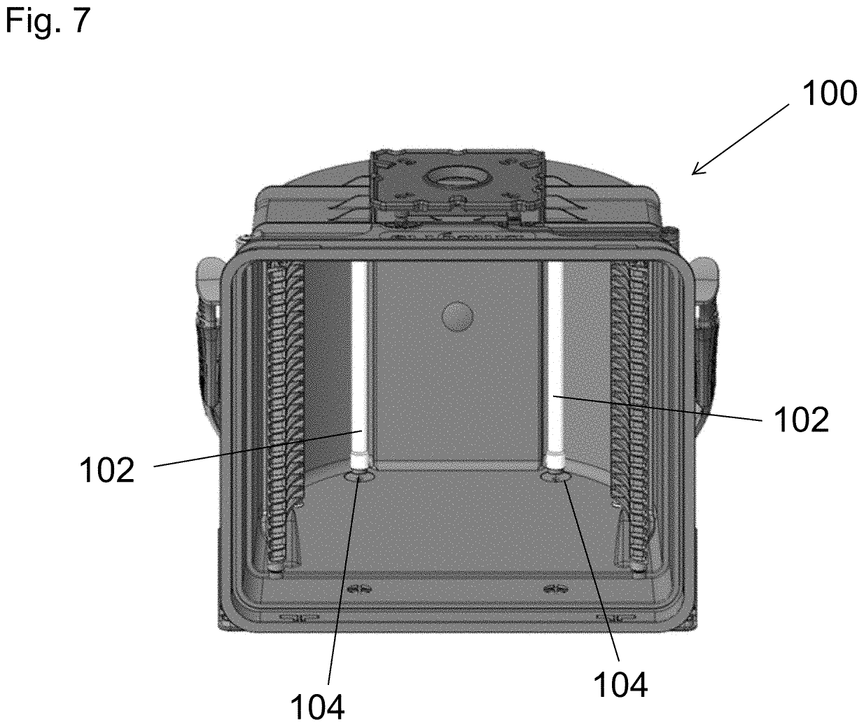

Referring to FIG. 7, in a conventional semiconductor substrate carrying container 100, purge fluid conditioning elements 102 are manually installed and mounted into conventional purge ports 104 from inside the interior space of the container 100. In other words, a person installing the elements 102 reaches inside the interior space of the container 100 and installs the elements 102 into the purge ports 104. However, this can cause human contamination of the interior environment of the container 100.

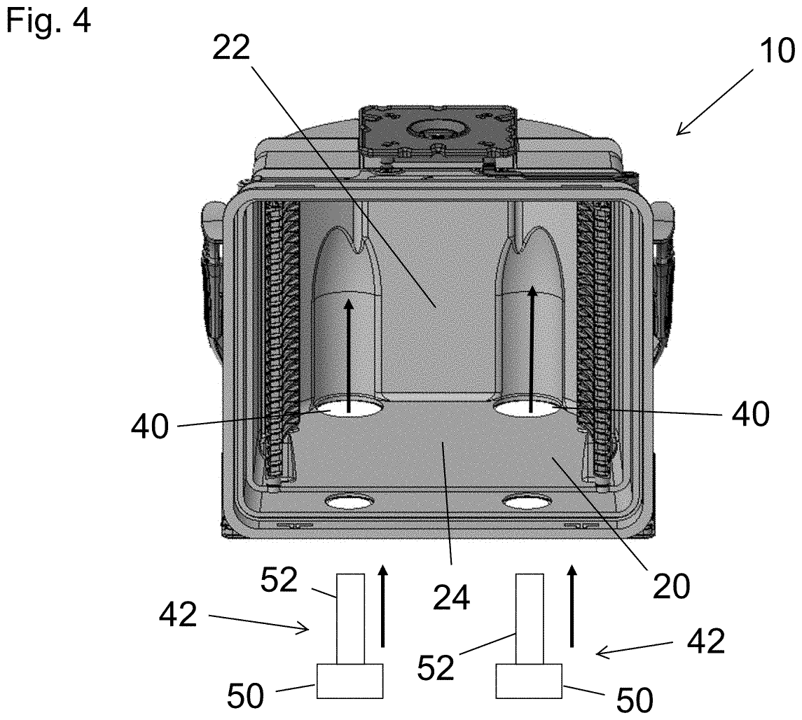

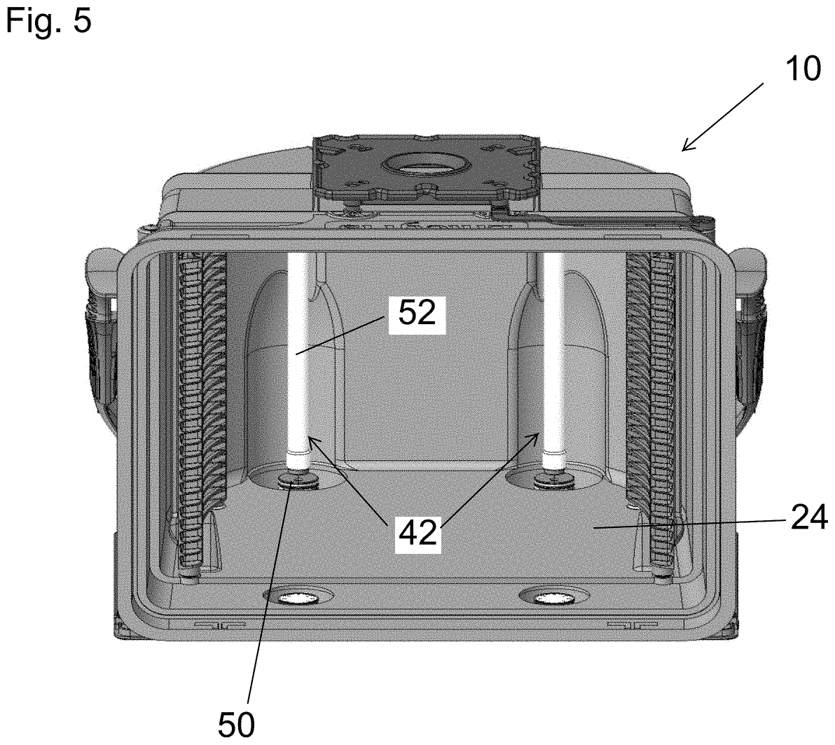

In contrast, the purge ports 40 of the container 10 are configured to permit installation of one or more purge fluid conditioning elements 42 (visible in FIGS. 4 and 5) in the interior space 24 by inserting the purge fluid conditioning elements 42 from outside the container 10. This eliminates the need for human access and entry into the interior space 24 of the container 10 to install the purge fluid conditioning elements 42, thereby eliminating such entry as a possible source of human contamination of the interior environment.

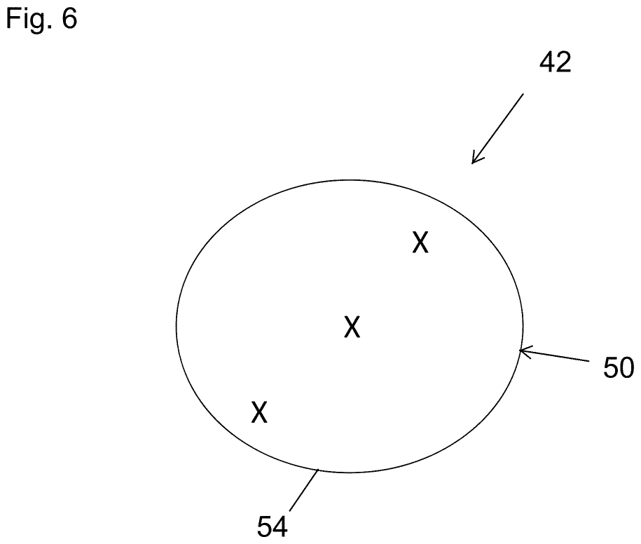

In particular, referring to FIGS. 1 and 3, the purge ports 40 of the container 10 are made larger than the purge ports in conventional containers, such as the container 100 in FIG. 6. The purge ports 40 are located at the rear of the container 10. As best seen in FIG. 3, the size and position of the purge ports 40 is such that at least a portion of the rear wall 22 is positioned forwardly of a portion of each one of the purge ports 40. In the illustrated example, the rear wall 22 is depicted as including a central portion 44 that is disposed between the two purge ports 40. A plane P, shown in dashed lines, of the central portion 44 of the rear wall 22 extends through each purge port 40 and is located forwardly of the most rearward portion, indicated by the dashed lines R₁ and R₂, of the perimeter edge of each purge port 40. Accordingly, at least the central portion 44 of the rear wall 22 is positioned forwardly of a portion, for example the most rearward portion of the perimeter edge, of each purge port 40. Alternatively, a portion of the rear wall 22, such as the central portion 44, can be described as being positioned closer to the front 28 of the container 10, or positioned closer to the front opening 30 of the container 10, than the most rearward portion of the perimeter edge of each purge port 40.

With reference to FIGS. 1-3, the size and position of the purge ports 40 is such that at least a portion of a rear wall 22 of the shell 12 is contiguous with a portion of a perimeter of each one of the purge ports 40. This is shown on the left purge port 40 in FIG. 3; the right purge port 40 can have a similar construction as the left purge port 40. In other words, at least a portion of the rear wall 22 and at least a portion of each one of the purge port 40 share a common border, or at least portions of the rear wall 22 form portions of the perimeter of the openings that define the purge ports 40. For example, referring to FIGS. 1-3, a rear portion of the perimeter of each purge port 40 forms a portion of the rear wall 22 from the location x to the location y. As best seen in FIGS. 1 and 2, between the locations x, y, the rear wall 22 is curved or bulged outwardly as those sections 46, 48 of the rear wall 22 follow the curvature of the rear perimeter of each purge port 40. In another embodiment shown on the right purge port 40 in FIG. 3, the purge port 40 can be slightly displaced from the rear wall so that a small lip 41 is formed between the rear wall and a portion of the perimeter of the purge port 40 between the locations x, y. In this embodiment, the left purge port 40 can have a similar construction as the right purge port 40.

Referring to FIGS. 1 and 2, the outwardly curved/outwardly bulged sections 46, 48 of the rear wall 22 extend a height H above the purge ports 40. In an embodiment, the bulged sections 46, 48 can extend a portion of the height of the shell 12 (as illustrated in FIGS. 1 and 2) or the bulged portions 46, 48 can extend the entire height of the shell 12 so that the height H extends substantially the entire distance from the bottom all 20 to the top wall 18. The configuration (for example, the curved shape and the height H) of the sections 46, 48 help to direct the flow of purge gas exiting the purge ports 40.

Referring to FIGS. 4 and 5, an example of installing the purge fluid conditioning elements 42 will be described. The purge fluid conditioning elements 42 can be any type of elements that are insertable into the interior space 24 for use in conditioning the environment in the interior space 24. Examples of the purge fluid conditioning elements 42 include, but are not limited to, a diffuser, a getter, a filter, combinations thereof, and others. Examples of purge fluid conditioning elements are disclosed in U.S. Pat. Nos. 9,054,144 and 10,347,517.

Referring initially to FIG. 4, assuming that the purge ports 40 are empty, the purge fluid conditioning elements 42 are brought into position under the bottom wall 20 allowing the elements 42 to be inserted through the purge ports 40 in the bottom wall 20 in the direction of the arrows. If the machine interface plate 32 is present, openings therein would be aligned with the purge ports 40 to also allow the elements 42 to be inserted through the plate 32. Each one of the elements 42 can include a base portion 50 that removably mounts the elements 42 in the purge ports 40 and a conditioning portion 52 that extends into the interior space 24.

With reference to FIG. 5, when each element 42 is fully installed, the base portion 50 is disposed in the purge port 40 removably attaching the element 42 in position, with the conditioning portion 52 extending upwardly into the interior space 24. In one embodiment, when the elements 42 are configured as diffusers, once the elements 42 are installed, a purge fluid can be directed into the elements 42 which distribute the purge fluid into the interior space 24.

Referring to FIG. 6, the base portion 50 is shown in top view as having a perimeter edge 54 which may be circular or have any other shape. In one embodiment, no portion of the conditioning portion 52 (shown in FIGS. 4 and 5) projects beyond the perimeter edge 54 of the base portion 50. Since no portion of the conditioning portion projects beyond the perimeter edge 54, insertion of the element 42 through the purge port is facilitated. However, in another embodiment, some portion of the conditioning portion 52 may project beyond the perimeter edge 54 in top view as long as the element 42 can still be installed through the purge port from the exterior of the container. In one embodiment, a central vertical axis X (extending into and out of the plane of FIG. 6) of the conditioning portion is disposed within the boundary of the perimeter edge 54. As indicated in FIG. 6, the central vertical axis X can be located at different positions including at a central position aligned with a central vertical axis of the base portion 50.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A semiconductor substrate carrying container, comprising:
a container shell having an interior space defined by first and second side walls, a top wall, a bottom wall, and a rear wall at a rear of the container shell, the interior space is sized to be able to receive a plurality of semiconductor substrates therein;
a front opening at a front of the container shell opposite the rear wall and through which a semiconductor substrate is able to be removed from and inserted into the interior space; and
at least one purge port extending through the bottom wall and opening entirely into the interior space, and at least a portion of the rear wall is positioned forwardly of a portion of the purge port.

2. The semiconductor substrate carrying container of claim 1, further comprising a diffuser, a getter, or a filter disposed in the at least one purge port.

3. The semiconductor substrate carrying container of claim 1, comprising at least two of the purge ports, each purge port extending through the bottom wall, each purge port opens entirely into the interior space, and at least a portion of the rear wall is positioned forwardly of a portion of each purge port.

4. The semiconductor substrate carrying container of claim 1, wherein at least a portion of the rear wall is contiguous with a portion of a perimeter of the at least one purge port.

5. The semiconductor substrate carrying container of claim 1, wherein the at least one purge port has a circular perimeter, and a portion of the rear wall that is adjacent to a portion of the circular perimeter of the at least one purge port is curved.

6. The semiconductor substrate carrying container of claim 1, wherein the semiconductor substrate carrying container comprises a front opening unified pod.

7. The semiconductor substrate carrying container of claim 1, wherein the semiconductor substrates comprise wafers or flat panels.

8. The semiconductor substrate carrying container of claim 1, wherein the portion of the rear wall that is positioned forwardly of the portion of the purge port extends from the bottom wall toward the top wall.

9. The semiconductor substrate carrying container of claim 8, wherein the portion of the rear wall that is positioned forwardly of the portion of the purge port extends from the bottom wall to the top wall.

10. A front opening unified pod, comprising:
a shell having a front opening and an interior space that is sized to be able to receive a plurality of semiconductor substrates therein;
at least one purge port extending through a bottom wall of the shell and opening entirely into the interior space; and
at least a portion of a rear wall of the shell is contiguous with a portion of a perimeter of the at least one purge port.

11. The front opening unified pod of claim 10, further comprising a diffuser, a getter, or a filter disposed in the at least one purge port.

12. The front opening unified pod of claim 10, comprising at least two of the purge ports, each purge port extending through the bottom wall and opening entirely into the interior space; and
portions of the rear wall of the shell are contiguous with portions of the perimeters of the at least two purge ports.

13. The front opening unified pod of claim 10, wherein the portion of the rear wall that is contiguous with the portion of the perimeter of the at least one purge port is configured to direct a flow of purge gas exiting the at least one purge port.

14. The front opening unified pod of claim 10, wherein the at least one purge port has a circular perimeter, and the portion of the rear wall that is contiguous with the portion of the circular perimeter of the at least one purge port is curved.

15. The front opening unified pod of claim 10, wherein the semiconductor substrates comprise wafers or flat panels.
